(19) United States
(12) Patent Application Publication
(10) Pub. No.: US 2016/0211243 A1
(43) Pub. Date: Jul. 21, 2016

(54) LAMINATED CHIP AND LAMINATED CHIP MANUFACTURING METHOD

(71) Applicant: FUJITSU LIMITED, Kawasaki-shi (JP)

(72) Inventors: MAKOTO SUWADA, Kawasaki (JP); Shunji Baba, Yokohama (JP); TAKASHI KANDA, Kawasaki (JP); NORIO KAINUMA, Nagano (JP)

(73) Assignee: FUJITSU LIMITED, Kawasaki-shi (JP)

(21) Appl. No.: 14/969,015

(22) Filed: Dec. 15, 2015

(30) Foreign Application Priority Data
Jan. 19, 2015 (JP) 2015-007734

(51) Int. Cl. H01L 25/065; H01L 23/00; H01L 25/00

(52) U.S. Cl. CPC H01L 25/0657; H01L 25/50; H01L 24/81; H01L 2225/06506; H01L 2225/06517; H01L 2224/81801

(57) ABSTRACT

A laminated chip includes: a first chip; a first wiring layer formed on the first chip; a second chip; a second wiring layer formed on the second chip; and a layer disposed between the first wiring layer and the second wiring layer, the layer includes an adhesive agent configured to bond the first wiring layer and the second wiring layer; a plurality of first bumps connected to the first wiring layer; a plurality of second bumps connected to the second wiring layer; and solder connected to the plurality of first bumps and the plurality of second bumps.

### CROSS-REFERENCE TO RELATED APPLICATIONS

This application is based upon and claims the benefit of prior Japanese Patent Application No. 2015-007734 filed on Jan. 19, 2015, the entire contents of which are incorporated herein by reference.

### FIELD

The embodiments relate to a laminated chip and a laminated chip manufacturing method.

### BACKGROUND

There is known a laminated chip (laminated type semiconductor device) in which a plurality of semiconductor chips are stacked. The laminated chip allows a packaging density to be increased, without expanding a mounting area, by adopting a three-dimensional structure. In addition, there is a method for electrically interconnecting semiconductor chips in the laminated chip using TSVs (Through Silicon Vias) penetrating through the semiconductor chips. Use of the TSVs enables a wiring line that interconnects the semiconductor chips to be shortened, and can speed up the operation of the laminated chip.
[Patent document 1] Japanese Laid-open Patent Publication No. 2009-182087
[Patent document 2] Japanese Laid-open Patent Publication No. 2014-68015

### SUMMARY

According to an aspect of the embodiments, a laminated chip includes a first chip; a first wiring layer formed on the first chip; a second chip; a second wiring layer formed on the second chip; and a layer disposed between the first wiring layer and the second wiring layer, the layer includes an adhesive agent configured to bond the first wiring layer and the second wiring layer; a plurality of first bumps connected to the first wiring layer; a plurality of second bumps connected to the second wiring layer; and solder connected to the plurality of first bumps and the plurality of second bumps.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a laminated chip according to a first embodiment;

FIG. 2 is an enlarged cross-sectional view of the laminated chip according to the first embodiment;

FIG. 3 is an enlarged cross-sectional view of the laminated chip according to the first embodiment;

FIGS. 4A and 4B are manufacturing process diagrams of the laminated chip according to the first embodiment;

FIGS. 5A and 5B are manufacturing process diagrams of the laminated chip according to the first embodiment;

FIG. 6 is a manufacturing process diagram of the laminated chip according to the first embodiment;

FIG. 7 is a manufacturing process diagram of the laminated chip according to the first embodiment;

FIG. 8 is an enlarged cross-sectional view of a laminated chip according to a second embodiment;

FIGS. 9A and 9B are manufacturing process diagrams of the laminated chip according to the second embodiment;

FIGS. 10A and 10B are manufacturing process diagrams of the laminated chip according to the second embodiment;

FIG. 11 is a manufacturing process diagram of the laminated chip according to the second embodiment;

FIG. 12 is a manufacturing process diagram of the laminated chip according to the second embodiment; and

FIG. 13 is a cross-sectional view illustrating a laminated chip.

### DESCRIPTION OF EMBODIMENTS

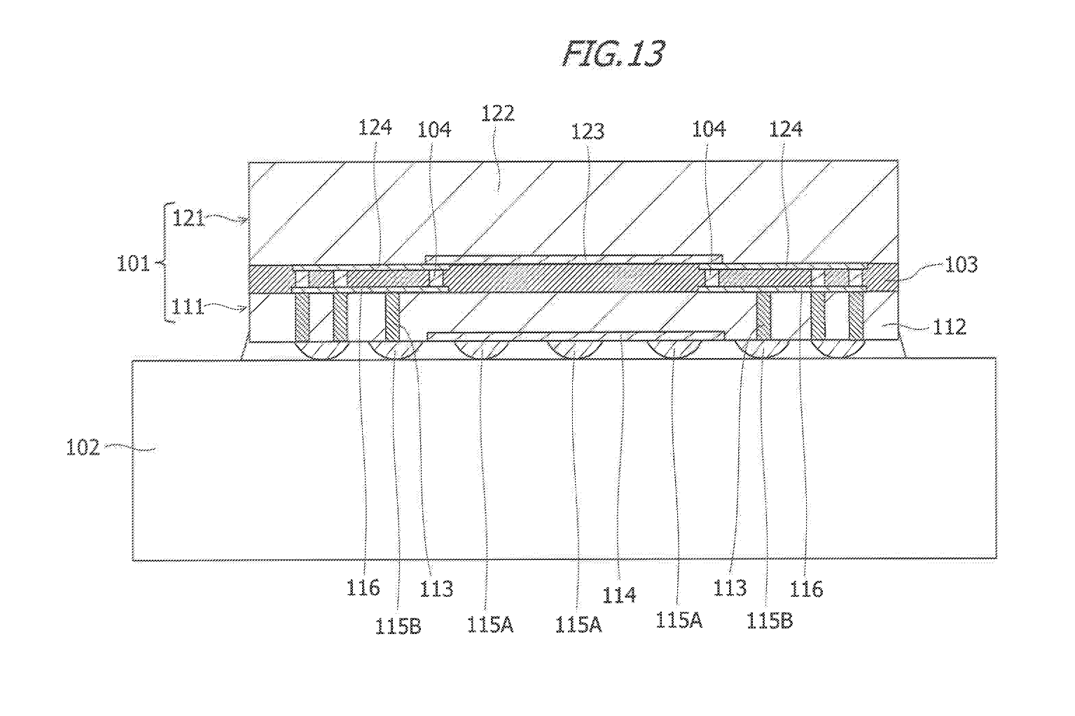

FIG. 13 is a cross-sectional view illustrating a laminated chip 101. As illustrated in FIG. 13, the laminated chip 101 includes semiconductor chips 111 and 121, and the semiconductor chips 111 and 121 are stacked and mounted on a wiring board 102. The semiconductor chips 111 and 121 are bonded with an adhesive agent 103 placed between the semiconductor chips 111 and 121. In the semiconductor chip 111, TSVs 113 penetrating through a substrate 112 are formed around a circuit 114. The semiconductor chip 111 is mounted on the wiring board 102 with a surface (circuit side) of the chip on which the circuit 114 is formed facing down. Solder balls 115A and 115B are formed on the circuit side of the semiconductor chip 111. Electrical power is supplied to the circuit 114 of the semiconductor chip 111 from the wiring board 102 through the solder balls 115A. Accordingly, in the lower semiconductor chip 111, electrical power is supplied from the wiring board 102 to the semiconductor chip 111 using a power feeding path in a vertical direction. A wiring layer 116 is formed on the opposite side of the circuit side of the substrate 112.

The semiconductor chip 121 includes a substrate 122 and a circuit 123. The semiconductor chip 121 is placed above the semiconductor chip 111 with a surface (circuit side) of the substrate 122 on which the circuit 123 is formed facing down. A wiring layer 124 is formed on the circuit side of the substrate 122. Electrical power is supplied from the wiring board 102 to the circuit 123 of the semiconductor chip 121 through the solder balls 115B, the TSVs 113, the wiring layer 116, a connecting part 104, and the wiring layer 124. Accordingly, in the upper semiconductor chip 121, electrical power is supplied from the wiring board 102 to the semiconductor chip 121 using power feeding paths in a vertical direction and a lateral direction. The wiring layers 116 and 124 are thin, and wiring lines within the wiring layers 116 and 124 are formed from copper foil having a thickness of several micrometers. The wiring lines within the wiring layers 116 and 124 therefore have large resistance values. Accordingly, electrical power supply to the semiconductor chip 121 is associated with a large voltage drop (power drop) in the power feeding path in the lateral direction.

Hereinafter, a laminated chip according to embodiments and a laminated chip manufacturing method will be described with reference to the accompanying drawings. The laminated chip and the laminated chip manufacturing method to be discussed hereinafter are merely illustrative, and therefore, the laminated chip and the laminated chip manufacturing method are not limited to configurations to be described hereinafter.

### First Embodiment

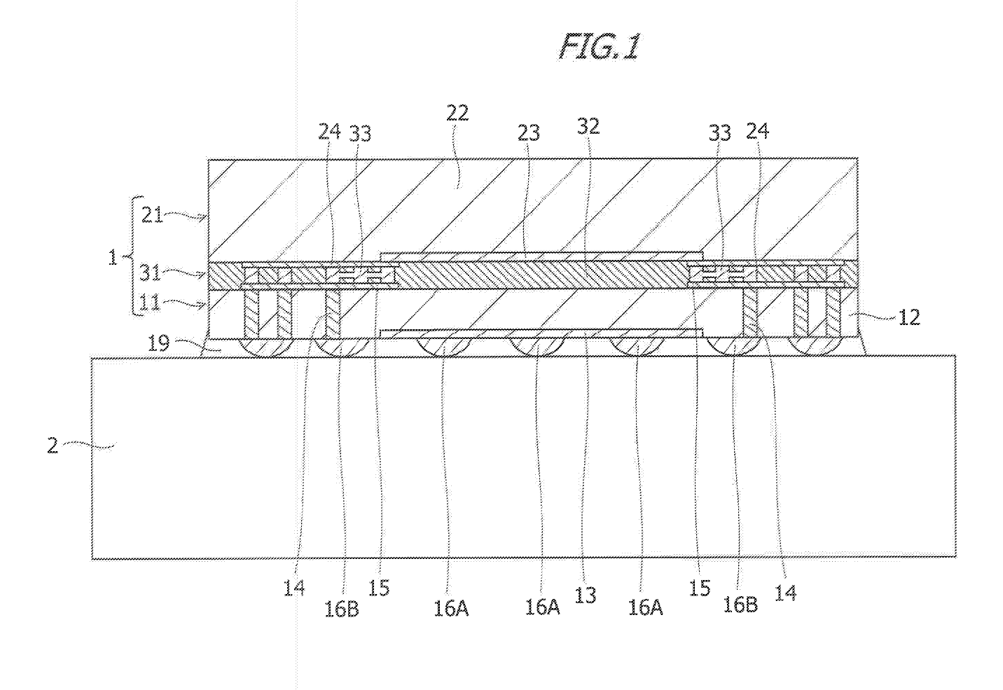

A laminated chip 1 according to a first embodiment will be described. FIG. 1 is a cross-sectional view illustrating the laminated chip 1 according to the first embodiment. The laminated chip 1 includes semiconductor chips 11 and 21 and an intermediate layer 31. The semiconductor chips 11 and 21 are stacked and mounted on a wiring board (printed circuit board) 2. The semiconductor chips 11 and 21 are, for example, logic chips such as LSI (Large Scale Integration) devices. The semiconductor chip 11 is one example of a first chip. The semiconductor chip 21 is one example of a second chip. The intermediate layer 31 is disposed between the semiconductor chip 11 and the semiconductor chip 21. The intermediate layer 31 is one example of a layer. The intermediate layer 31 includes an adhesive agent 32 and a connecting part 33.

The semiconductor chip 11 includes a semiconductor substrate 12, a circuit 13, TSVs 14 and a wiring layer (rewiring layer) 15. The semiconductor substrate 12 is, for example, a silicon substrate. The circuit 13 is formed on a first surface of the semiconductor substrate 12. Accordingly, the first surface of the semiconductor substrate 12 is the surface (circuit side) of the semiconductor substrate 12 on which the circuit 13 is formed. The circuit 13 is formed in a central portion of the first surface of the semiconductor substrate 12. The TSVs 14 penetrate through the semiconductor substrate 12. The TSV 14 are formed in the semiconductor substrate 12 by, for example, forming holes in the semiconductor substrate 12 by means of etching and performing copper plating on the side surfaces of the holes. The TSVs 14 are formed around the circuit 13 in the outer peripheral portion of the semiconductor substrate 12. One end of each TSV 14 is exposed out of the first surface of the semiconductor substrate 12, whereas the other end of the TSV 14 is exposed out of the second surface of the semiconductor substrate 12. The second surface of the semiconductor substrate 12 is a surface on the opposite side of the first surface of the semiconductor substrate 12. The wiring layer 15 is formed on the second surface of the semiconductor substrate 12. The wiring layer 15 is one example of a first wiring layer.

The semiconductor chip 11 is mounted on the wiring board 2 with the first surface of the semiconductor substrate 12 facing down. Pluralities of solder balls 16A and 16B are formed on the first surface of the semiconductor substrate 12. Electrical power is supplied from the wiring board 2 to the circuit 13 of the semiconductor chip 11 through the solder balls 16A. Accordingly, electrical power is supplied from the wiring board 2 to the semiconductor chip 11 using a power feeding path (electrically-conducting path) in a vertical direction (thickness-direction) in the lower semiconductor chip 11. Underfill resin 19 is formed between the semiconductor chip 11 and the wiring board 2.

The semiconductor chip 21 includes a semiconductor substrate 22, a circuit 23 and a wiring layer (rewiring layer) 24. The semiconductor substrate 22 is, for example, a silicon substrate. The circuit 23 and the wiring layer 24 are formed on a first surface of the semiconductor substrate 22. Accordingly, the first surface of the semiconductor substrate 22 is the surface (circuit side) of the semiconductor substrate 22 on which the circuit 23 is formed. The circuit 23 is formed in a central portion of the first surface of the semiconductor substrate 22. The semiconductor chip 21 is placed above the semiconductor chip 11 with the first surface of the semiconductor substrate 22 facing down. The wiring layer 24 is one example of a second wiring layer.

Electrical power is supplied from the wiring board 2 to the circuit 23 of the semiconductor chip 21 through the solder balls 16B, the TSVs 14, the wiring layer 15, the connecting part 33, and the wiring layer 24. Accordingly, electrical power is supplied from the wiring board 2 to the semiconductor chip 21 using power feeding paths in a vertical direction (thickness-direction) and a lateral direction (planar-direction) in the lower semiconductor chip 21.

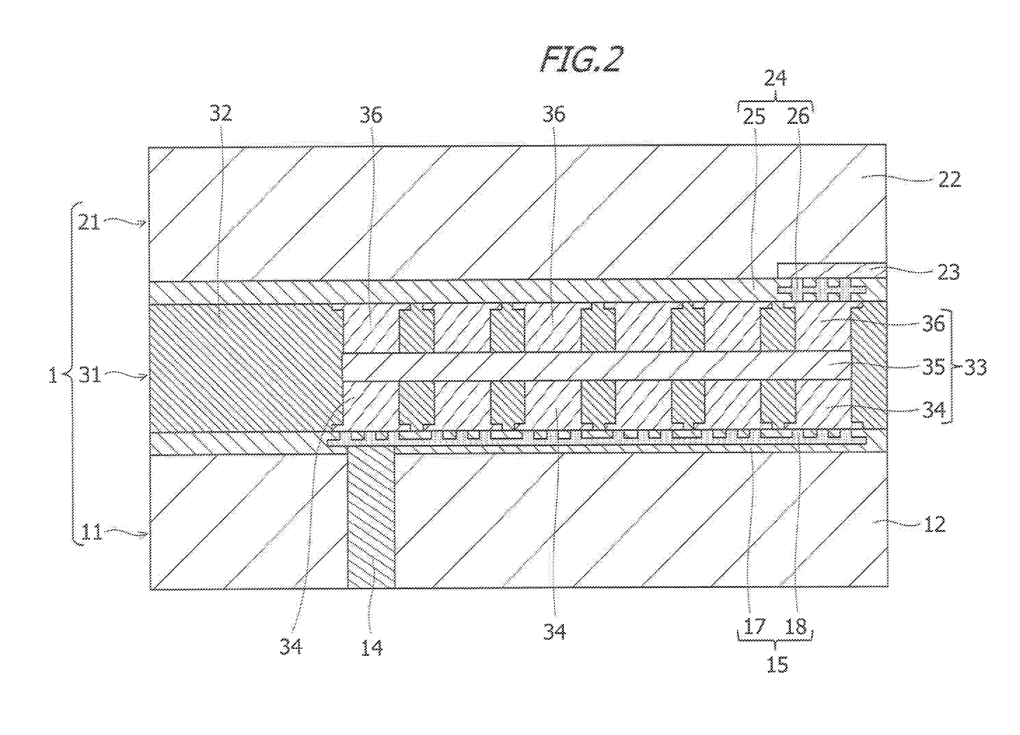

FIG. 2 is an enlarged cross-sectional view of the laminated chip 1 according to the first embodiment, illustrating details on the intermediate layer 31. The intermediate layer 31 includes an adhesive agent 32 and the connecting part 33. The adhesive agent 32 bonds the semiconductor chip 11 and the semiconductor chip 21. The adhesive agent 32 also bonds the wiring layers 15 and 24. The connecting part 33 includes a plurality of microbumps 34, joining solder 35, and a plurality of microbumps 36. The microbumps 34 are connected to the wiring layer 15, whereas the microbumps 36 are connected to the wiring layer 24. Each microbump 34 is one example of a first bump. The joining solder 35 is one example of solder. Each microbump 36 is one example of a second bump.

The joining solder 35 has contact with the upper surfaces of the microbumps 34 and with the upper surfaces of the microbumps 36. Consequently, the microbumps 34 and 36 disposed so as to face each other are joined together with the joining solder 35. The upper surface of each microbump 34 is a surface on the opposite side of the surface (lower surface) thereof in contact with the wiring layer 15. Likewise, the upper surface of each microbump 36 is a surface on the opposite side of the surface (lower surface) thereof in contact with the wiring layer 24. The material of the microbumps 34 and 36 is, for example, Cu (copper). The material of the joining solder 35 is, for example, Sn (tin).

The wiring layer 15 includes resin 17 and a wiring line 18. The resin 17 covers the wiring line 18. The material of the wiring line 18 is, for example, Cu. The TSV 14 is electrically connected to a microbump 34 through the wiring line 18. The wiring layer 24 includes resin 25 and a wiring line 26. The resin 25 covers the wiring line 26. The circuit 23 is electrically connected to a microbump 36 through the wiring line 26.

The joining solder 35 is connected (joined) to the plurality of microbumps 34 and the plurality of microbumps 36. The joining solder 35 electrically connects the plurality of microbumps 34 and the plurality of microbumps 36. That is, the joining solder 35 electrically connects the microbumps 34 and the microbumps 36 disposed so as to face each other. In addition, the joining solder 35 electrically connects adjacent microbumps 34. Yet additionally, the joining solder 35 electrically connects adjacent microbumps 36.

Electrical power is supplied from the wiring board 2 to the circuit 23 through the solder balls 16B, the TSVs 14, the wiring line 18, the microbumps 34, the joining solder 35, the microbumps 36, and the wiring line 26. The resistance value of Cu is 1.7×10⁻⁸ (Ω·m), whereas the resistance value of Sn is 1.1×10⁻⁷ (Ω·m). Accordingly, the thickness of the joining solder 35 is preferably approximately 6.7 times the thickness of the wiring lines 18 and 26, or larger. For example, when the thickness of the wiring lines 18 and 26 is 1.5 μm, then the thickness of the joining solder 35 is preferably 10 μm or larger. The thickness of the joining solder 35 is the distance between the microbumps 34 and the microbumps 36 disposed so as to face each other.

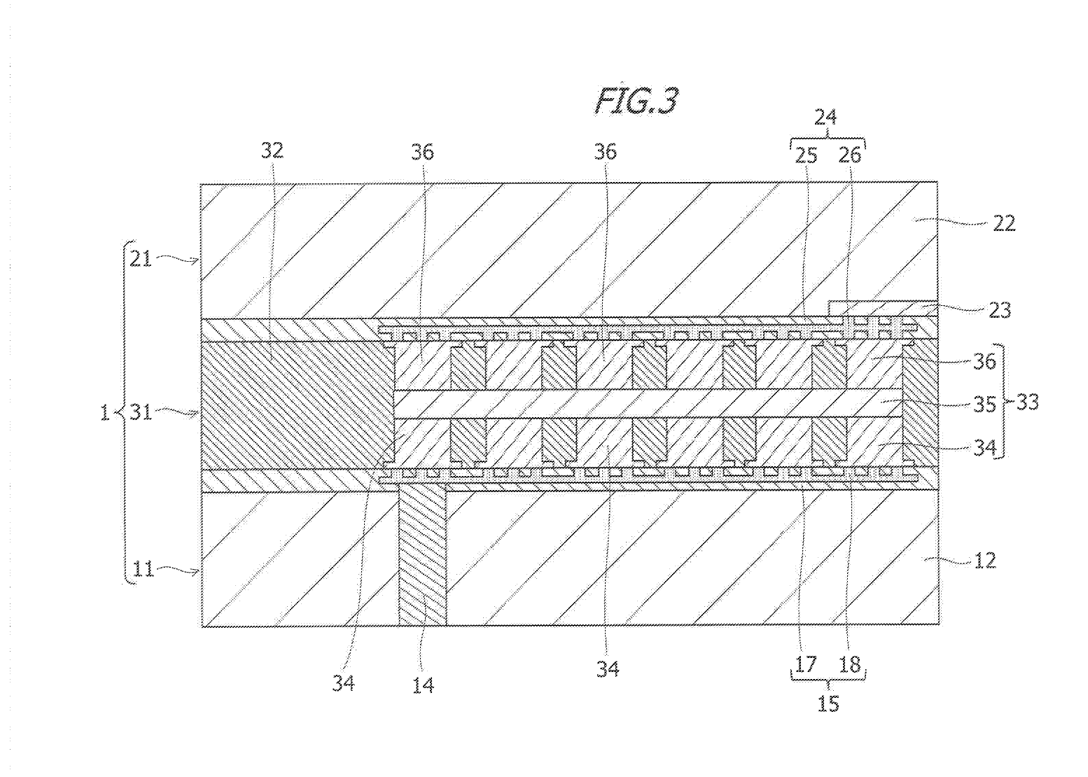

In the structural example of the laminated chip 1 illustrated in FIG. 2, the wiring line 26 is disposed on one microbump 36. Without limitation to the structural example of the laminated chip 1 illustrated in FIG. 2, the wiring line 26 may be disposed on a plurality of microbumps 36, as in the structural example of the laminated chip 1 illustrated in FIG. 3. In this case, the wiring line 26 electrically connects adjacent microbumps 36.

According to the laminated chip 1 in accordance with the first embodiment, the microbumps 34 and 36, adjacent microbumps 34, and adjacent microbumps 36 are electrically connected, respectively, through the joining solder 35. Consequently, the voltage drop of a power feeding path in a lateral direction is suppressed in electrical power supply from the wiring board 2 to the semiconductor chip 21, thus reducing a voltage drop in electrical power supply to the semiconductor chip 21.

<<Manufacturing Method>>

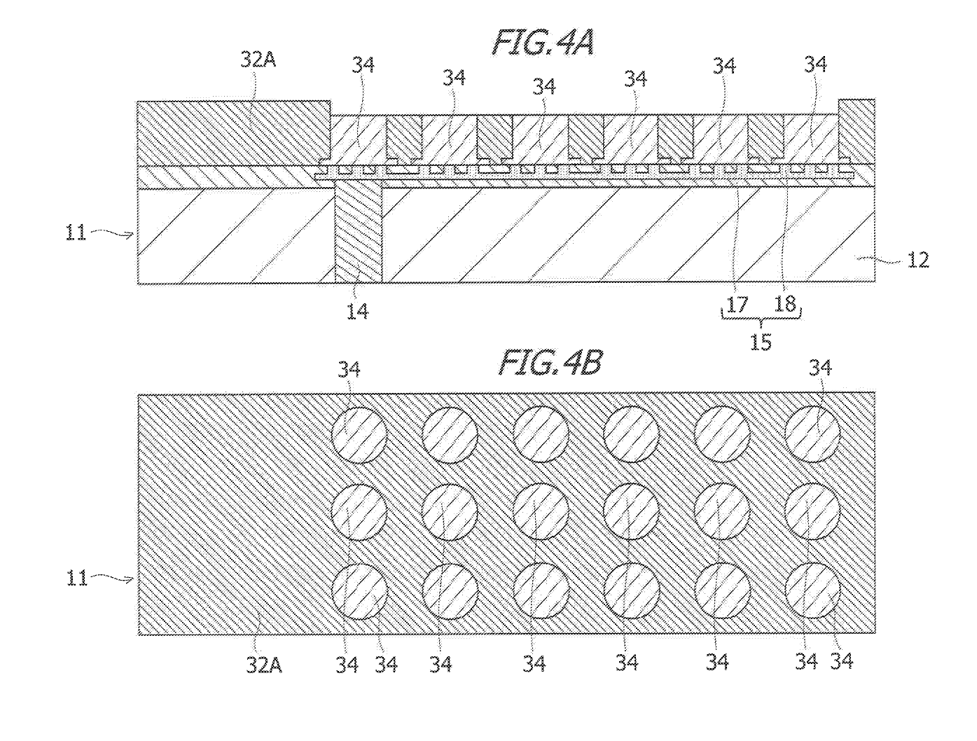

A description will be made of a method for manufacturing the laminated chip 1 according to the first embodiment. FIGS. 4A and 4B are manufacturing process diagrams of the laminated chip 1 according to the first embodiment. FIG. 4A is a partial cross-sectional view of the semiconductor chip 11, whereas FIG. 4B is a partial top view of the semiconductor chip 11. First, the semiconductor chip 11 is prepared. Next, the wiring layer 15 is formed on the second surface of the semiconductor substrate 12, thereby forming the wiring layer 15 in the semiconductor chip 11. Subsequently, a plurality of microbumps 34 are disposed on the wiring layer 15, and the wiring line 18 and the plurality of microbumps 34 are joined together, thereby connecting the plurality of microbumps 34 to the wiring layer 15. Next, the adhesive agent 32A is formed (applied) on the wiring layer 15.

As illustrated in FIGS. 4A and 4B, the adhesive agent 32A is formed on the wiring layer 15, so that the microbumps 34 are exposed out of the adhesive agent 32A. When the adhesive agent 32A is a thermosetting insulating film, the adhesive agent 32A is heated and applied onto the wiring layer 15.

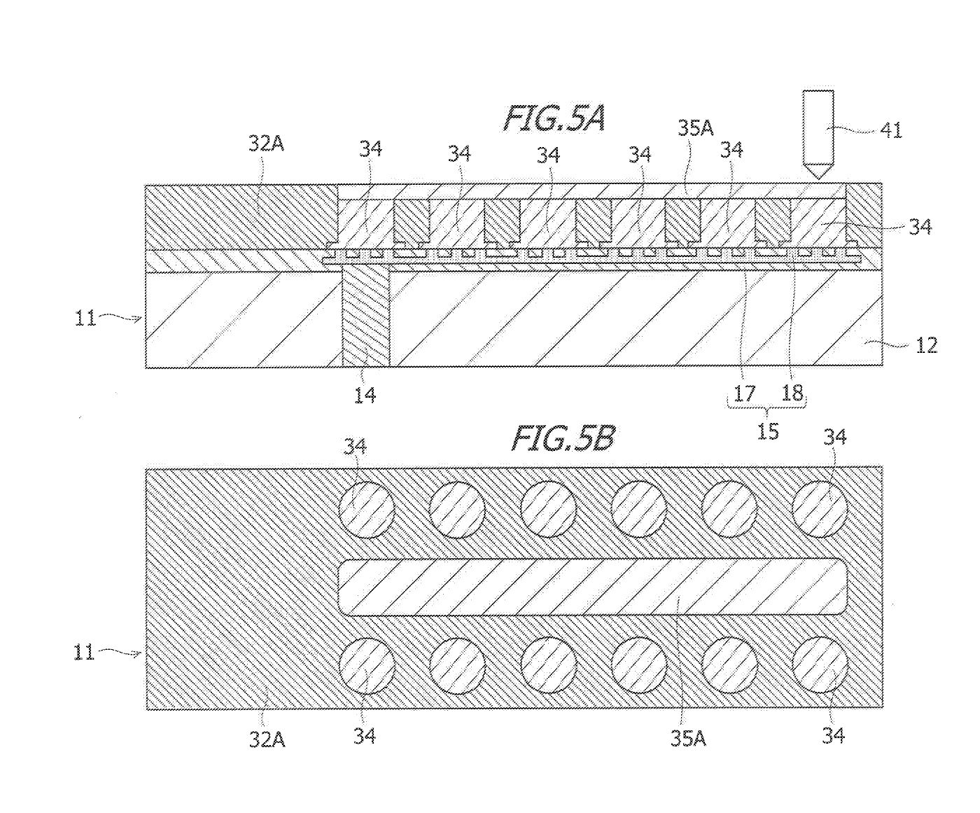

FIGS. 5A and 5B are manufacturing process diagrams of the laminated chip 1 according to the first embodiment. FIG. 5A is a cross-sectional view of the semiconductor chip 11, whereas FIG. 5B is a top view of the semiconductor chip 11. As illustrated in FIGS. 5A and 5B, the joining solder 35A is supplied from a dispenser 41 to form (apply) the joining solder 35A on the adhesive agent 32A and the plurality of microbumps 34. In this case, the joining solder 35A is formed on a portion of the adhesive agent 32A between adjacent microbumps 34 and on a plurality of microbumps 34 exposed out of the adhesive agent 32A. Accordingly, the joining solder 35A is formed on the plurality of microbumps 34 lining up in a predetermined direction. The predetermined direction is, for example, a direction toward the central portion from the outer peripheral portion of the semiconductor chip 11 (or the semiconductor substrate 12).

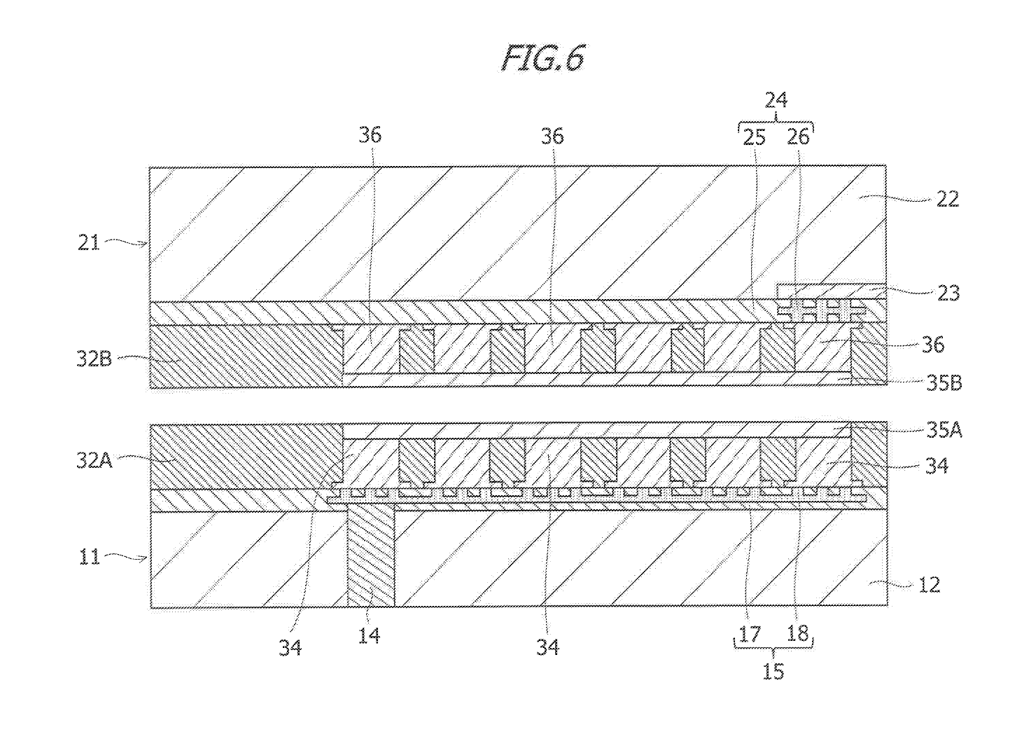

FIG. 6 is a manufacturing process diagram of the laminated chip 1 according to the first embodiment. As illustrated in FIG. 6, the semiconductor chips 11 and 21 are aligned with each other. In this case, the semiconductor chips 11 and 21 are disposed so that the plurality of microbumps 34 and the plurality of microbumps 36 face each other. The semiconductor chip 21 is processed in the same way as the semiconductor chip 11. That is, the wiring layer 24 is formed on the semiconductor chip 21. Subsequently, a plurality of microbumps 36 are connected to the wiring layer 24. Next, an adhesive agent 32B is formed (applied) to the wiring layer 24. Subsequently, the joining solder 35B is formed on the adhesive agent 32B and the plurality of microbumps 36. In this case, the joining solder 35B is formed on a portion of the adhesive agent 32B between adjacent microbumps 36 and on a plurality of microbumps 36 exposed out of the adhesive agent 32B. Accordingly, the joining solder 35B is formed on the plurality of microbumps 36 lining up in a predetermined direction. The predetermined direction is, for example, a direction toward the central portion from the outer peripheral portion of the semiconductor chip 21 (or the semiconductor substrate 22).

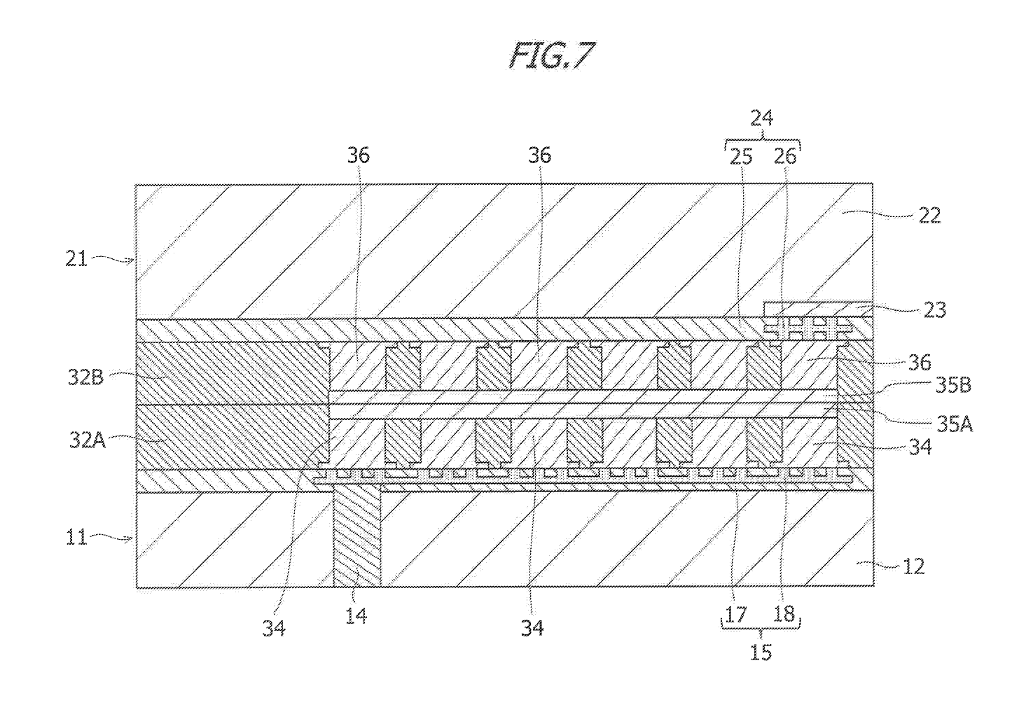

FIG. 7 is a manufacturing process diagram of the laminated chip 1 according to the first embodiment. As illustrated in FIG. 7, the adhesive agent 32A formed on the semiconductor chip 11 side and the adhesive agent 32B formed on the semiconductor chip 21 side are brought into contact with each other. Likewise, the joining solder 35A formed on the semiconductor chip 11 side and the joining solder 35B formed on the semiconductor chip 21 side are brought into contact with each other. Next, a heating treatment is performed to attach the adhesive agent 32A formed on the semiconductor chip 11 side and the adhesive agent 32B formed on the semiconductor chip 21 side to each other and join together the joining solder 35A formed on the semiconductor chip 11 side and the joining solder 35B formed on the semiconductor chip 21 side. A pressurization treatment may be performed along with the heating treatment. The pressurization treatment is a treatment used to press the semiconductor chip 11 against the semiconductor chip 21, or press the semiconductor chip 21 against the semiconductor chip 11.

By attaching the adhesive agent 32A formed on the semiconductor chip 11 side and the adhesive agent 32B formed on the semiconductor chip 21 side to each other, a combined adhesive agent 32 is formed between the wiring layers 15 and 24. This process forms the adhesive agent 32 for bonding the wiring layers 15 and 24. By joining together the joining solder 35A formed on the semiconductor chip 11 side and the joining solder 35B formed on the semiconductor chip 21 side, combined joining solder 35 is formed between the plurality of microbumps 34 and the plurality of microbumps 36.

### Second Embodiment

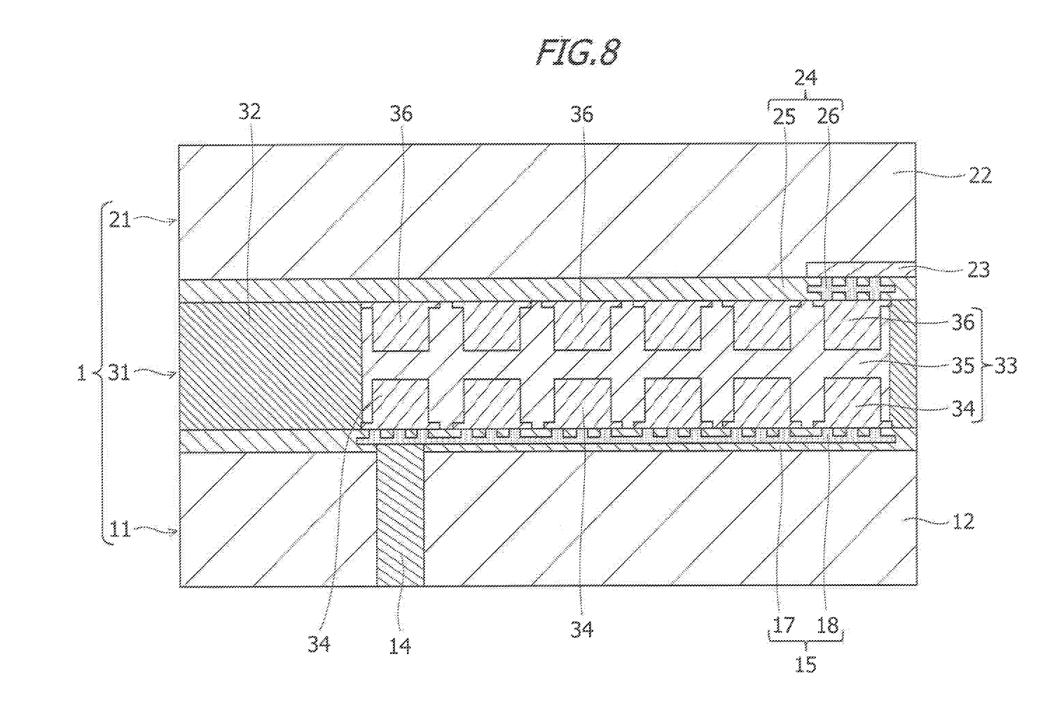

A laminated chip 1 according to a second embodiment will be described. Constituent elements the same as those in the first embodiment are denoted by the same reference numerals and characters and will not be explained again. FIG. 8 is an enlarged cross-sectional view of the laminated chip 1 according to the second embodiment, illustrating details on the intermediate layer 31. The joining solder 35 covers the microbumps 34 and 36. The joining solder 35 is buried between adjacent microbumps 34 and between adjacent microbumps 36. The joining solder 35 may cover the entire upper and side surfaces of the microbumps 34 or parts of the upper and side surfaces of the microbumps 34. The joining solder 35 may cover the entire upper and side surfaces of the microbumps 36 or parts of the upper and side surfaces of the microbumps 36. The wiring line 26 may be disposed on the plurality of microbumps 34 as in the first embodiment. In this case, the wiring line 26 electrically connects adjacent microbumps 36.

The joining solder 35 has a first thickness and a second thickness. The first thickness of the joining solder 35 is the distance between the microbumps 34 and 36 disposed so as to face each other. The second thickness of the joining solder 35 is the distance between the wiring layers 15 and 24. In the laminated chip 1 according to the second embodiment, the joining solder 35 is buried between adjacent microbumps 34 and between adjacent microbumps 36. Since the second thickness of the joining solder 35 is larger than the first thickness thereof, the resistance value of the joining solder 35 is reduced. In addition, the microbumps 34 and 36 are used as parts of a lateral power feeding path in electrical power supply from the wiring board 2 to the semiconductor chip 21. Consequently, the voltage drop of the lateral power feeding path is further suppressed in electrical power supply from the wiring board 2 to the semiconductor chip 21, thus further reducing the voltage drop in electrical power supply to the semiconductor chip 21. For example, when the second thickness of the joining solder 35 is approximately 30 μm, then a portion of the joining solder 35 having the second thickness corresponds to a Cu wiring line having a thickness of approximately 4.5 μm.

<<Manufacturing Method>>

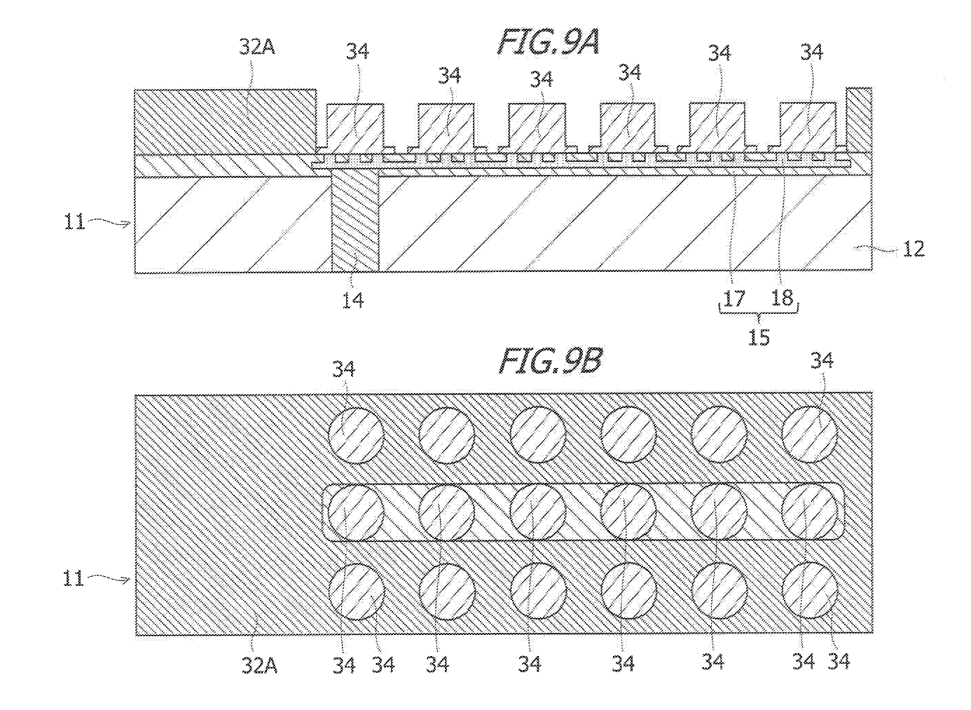

A description will be made of a method for manufacturing the laminated chip 1 according to the second embodiment. FIGS. 9A and 9B are manufacturing process diagrams of the laminated chip 1 according to the second embodiment. FIG. 9A is a partial cross-sectional view of the semiconductor chip 11, whereas FIG. 9B is a partial top view of the semiconductor chip 11. In the second embodiment, there is carried out the same step as the step of forming the adhesive agent 32A and the microbumps 34 in the first embodiment (see FIGS. 4A and 4B). After the step of forming the adhesive agent 32A and the microbumps 34 is carried out, the adhesive agent 32A is partially removed using laser, as illustrated in FIGS. 9A and 9B. In this case, a portion of the adhesive agent 32A between adjacent microbumps 34 is removed in a plurality of microbumps 34 lining up in a predetermined direction. The predetermined direction is, for example, a direction toward the central portion from the outer peripheral portion of the semiconductor chip 11 (or the semiconductor substrate 12).

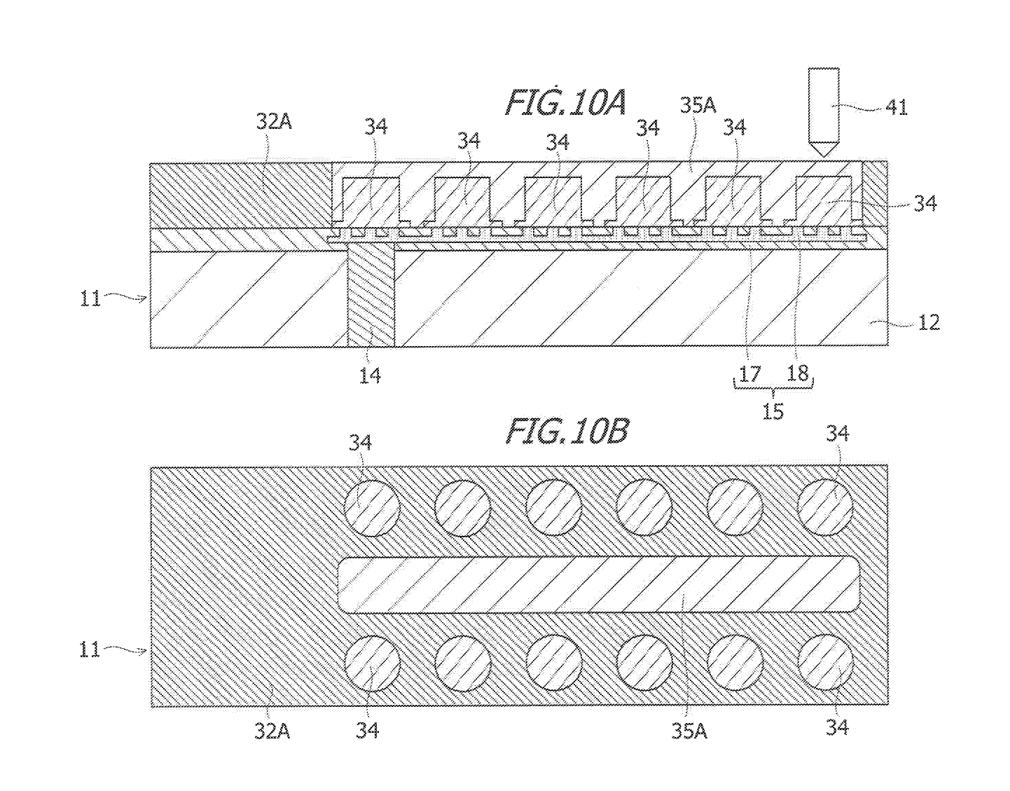

FIGS. 10A and 10B are manufacturing process diagrams of the laminated chip 1 according to the second embodiment. FIG. 10A is a cross-sectional view of the semiconductor chip 11, whereas FIG. 10B is a top view of the semiconductor chip 11. As illustrated in FIGS. 10A and 10B, the joining solder 35A is supplied from a dispenser 41 to form (apply) the joining solder 35A on the plurality of microbumps 34. In this case, the joining solder 35A is formed on the plurality of microbumps 34 exposed out of the adhesive agent 32A, and buried between adjacent microbumps 34. Accordingly, the joining solder 35A is formed on the plurality of microbumps 34 lining up in a predetermined direction. The predetermined direction is, for example, a direction toward the central portion from the outer peripheral portion of the semiconductor chip 11 (or the semiconductor substrate 12).

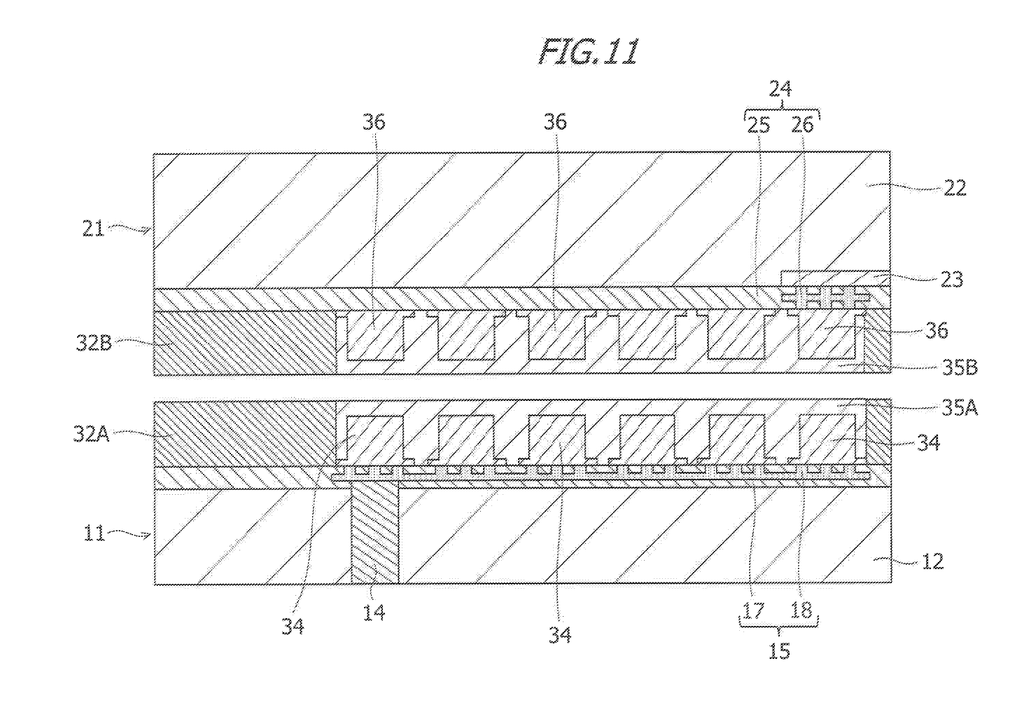

FIG. 11 is a manufacturing process diagram of the laminated chip 1 according to the second embodiment. As illustrated in FIG. 11, the semiconductor chips 11 and 21 are aligned with each other. In this case, the semiconductor chips 11 and 21 are disposed so that the plurality of microbumps 34 and the plurality of microbumps 36 face each other. The semiconductor chip 21 is processed in the same way as the semiconductor chip 11. That is, the wiring layer 24 is formed on the semiconductor chip 21. Subsequently, a plurality of microbumps 36 are connected to the wiring layer 24. Next, an adhesive agent 32B is formed (applied) on the wiring layer 24. Subsequently, a portion of the adhesive agent 32B between adjacent microbumps 36 is removed. Next, the joining solder 35B is formed on the plurality of microbumps 36 exposed out of the adhesive agent 32B, and buried between adjacent microbumps 36. Consequently, the joining solder 35B is formed on the plurality of microbumps 36 lining up in a predetermined direction. The predetermined direction is, for example, a direction toward the central portion from the outer peripheral portion of the semiconductor chip 21 (or the semiconductor substrate 22).

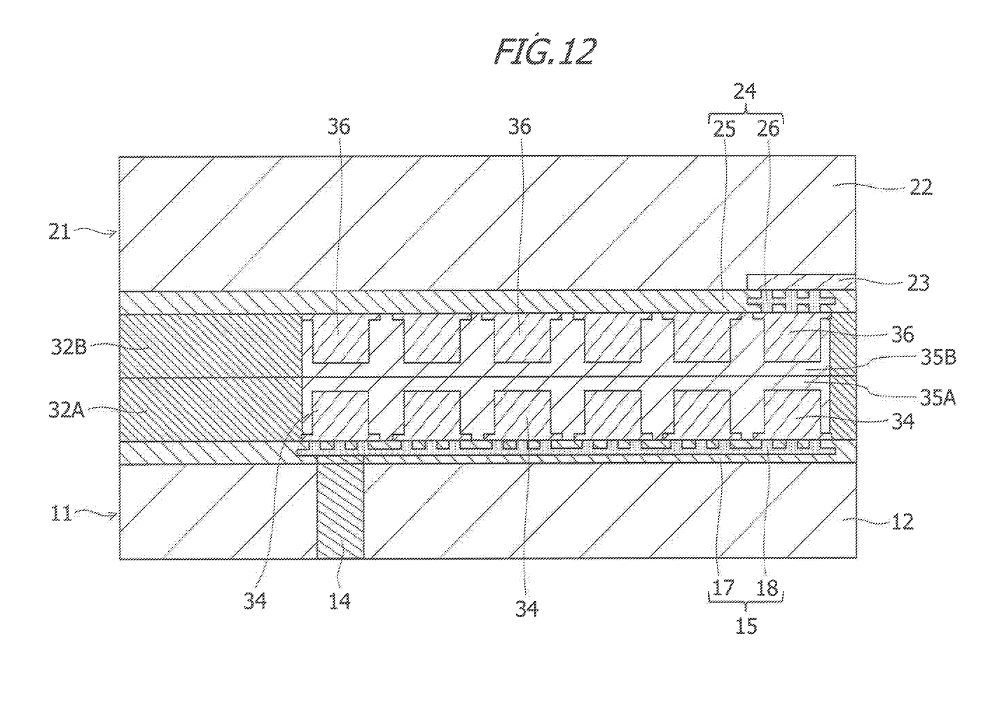

FIG. 12 is a manufacturing process diagram of the laminated chip 1 according to the second embodiment. As illustrated in FIG. 12, the adhesive agent 32A formed on the semiconductor chip 11 side and the adhesive agent 32B formed on the semiconductor chip 21 side are brought into contact with each other. Likewise, the joining solder 35A formed on the semiconductor chip 11 side and the joining solder 35B formed on the semiconductor chip 21 side are brought into contact with each other. Next, a heating treatment is performed to attach the adhesive agent 32A formed on the semiconductor chip 11 side and the adhesive agent 32B formed on the semiconductor chip 21 side to each other and join together the joining solder 35A formed on the semiconductor chip 11 side and the joining solder 35B formed on the semiconductor chip 21 side. A pressurization treatment may be performed along with the heating treatment. The pressurization treatment is a treatment used to press the semiconductor chip 11 against the semiconductor chip 21, or press the semiconductor chip 21 against the semiconductor chip 11.

By attaching the adhesive agent 32A formed on the semiconductor chip 11 side and the adhesive agent 32B formed on the semiconductor chip 21 side to each other, a combined adhesive agent 32 is formed between the wiring layers 15 and 24. This process forms the adhesive agent 32 for bonding the wiring layers 15 and 24. By joining together the joining solder 35A formed on the semiconductor chip 11 side and the joining solder 35B formed on the semiconductor chip 21 side, combined joining solder 35 is formed between the plurality of microbumps 34 and the plurality of microbumps 36.

According to the laminated chips 1 in accordance with the first and second embodiments, it is possible to reduce a voltage drop in electrical power supply to the semiconductor chip 21 without using expensive rewiring layers and separately-arranged interposers. Accordingly, a large current can be supplied to the laminated chip 1 while preventing an increase in the manufacturing cost of the laminated chip 1. For example, heat transfer from the semiconductor chip 11 to the semiconductor chip 21 is decreased when an interposer is disposed between the semiconductor chips 11 and 21. According to the laminated chips 1 in accordance with the first and second embodiments, any interposer is not disposed between the semiconductor chips 11 and 21. A voltage drop in electrical power supply to the semiconductor chip 21 can therefore be reduced while maintaining the effect of cooling the laminated chip 1. In addition, according to the laminated chips 1 in accordance with the first and second embodiments, the plurality of microbumps 34 and the plurality of microbumps 36 are joined together with the joining solder 35, thereby improving heat transfer from the semiconductor chip 11 to the semiconductor chip 21.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that the various changes, substitutions, and alterations could be made hereto without departing from the spirit and scope of the invention.

What is claimed is:

1. A laminated chip comprising:
a first chip;
a first wiring layer formed on the first chip;
a second chip;
a second wiring layer formed on the second chip; and
a layer disposed between the first wiring layer and the second wiring layer, the layer including
an adhesive agent configured to bond the first wiring layer and the second wiring layer;
a plurality of first bumps connected to the first wiring layer;
a plurality of second bumps connected to the second wiring layer; and
solder connected to the plurality of first bumps and the plurality of second bumps.

2. The laminated chip according to claim 1, wherein the solder is buried between adjacent ones of the first bumps and between adjacent ones of the second bumps.

3. A laminated chip manufacturing method, comprising:
forming a first wiring layer on a first chip;
connecting a plurality of first bumps to the first wiring layer;
forming a first adhesive agent on the first wiring layer;
forming first solder on a plurality of the first bumps exposed out of the first adhesive agent;
forming a second wiring layer on a second chip;
connecting a plurality of second bumps to the second wiring layer;
forming a second adhesive agent on the second wiring layer;
forming second solder on a plurality of the second bumps exposed out of the second adhesive agent;
attaching the first adhesive agent and the second adhesive agent to each other; and
joining together the first solder and the second solder.

4. The laminated chip manufacturing method according to claim 3, comprising:
removing a portion of the first adhesive agent between adjacent ones of the first bumps; and
removing a portion of the second adhesive agent between adjacent ones of the second bumps,
wherein the forming the first solder includes burying the first solder between the adjacent ones of the first bumps, and
the forming the second solder includes burying the second solder between the adjacent ones of the second bumps.
